(19) United States
(12) Patent Application Publication
(10) Pub. No.: US 2026/0128738 A1
(43) Pub. Date: May 7, 2026

(54) CIRCUIT PROTECTION SYSTEMS AND RELATED METHODS

(71) Applicant: SEMICONDUCTOR COMPONENTS INDUSTRIES, LLC, Scottsdale, AZ (US)

(72) Inventor: Vijay B. RENTALA, Plano, TX (US)

(73) Assignee: SEMICONDUCTOR COMPONENTS INDUSTRIES, LLC, Scottsdale, AZ (US)

(21) Appl. No.: 19/376,814

(22) Filed: Oct. 31, 2025

Related U.S. Application Data
(60) Provisional application No. 63/715,480, filed on Nov. 1, 2024.

(51) Int. Cl. H03K 17/0814; H03K 17/18

(52) U.S. Cl. CPC H03K 17/08142; H03K 17/18; H03K 2217/0027; H03K 2217/0081

(57) ABSTRACT

Circuit implementations may include a sensing field effect transistor, a gate of the sensing field effect transistor coupled with a gate of a silicon carbide transistor; and a driver integrated circuit including a differential amplifier coupled with a drain of the sensing field effect transistor and configured to output a gate reference voltage in response to receiving a drain current from the sensing field effect transistor. A first transistor may be included where a gate of the first transistor may be coupled to the gate reference voltage and a collector is coupled to a reference current source forming a current mirror. A first comparator may be coupled to the collector and configured to output a detected voltage signal when the gate reference voltage reaches a predetermined voltage level and the driver integrated circuit receives the detected voltage signal identifying a first fault condition and shuts down the silicon carbide transistor.

### CROSS REFERENCE TO RELATED APPLICATIONS

This document claims the benefit of the filing date of U.S. Provisional Patent Application 63/715,480, entitled “Circuit Protection Systems and Related Methods” to Vijay Rentala which was filed on 11/1/2024, the disclosure of which is hereby incorporated entirely herein by reference.

### BACKGROUND

### 1. Technical Field

Aspects of this document relate generally to semiconductor devices, such as field effect transistors.

### 2 Background

Various semiconductor devices work to control the flow of electricity. Semiconductor devices are utilized in various applications including switching applications. Semiconductor devices include various packages that allow for the packaged devices to find mechanical support and form electrical connections with a circuit board or motherboard to which they are attached.

### SUMMARY

Implementations of a circuit protection system may include a sensing field effect transistor, a gate of the sensing field effect transistor configured to be coupled with a gate of a silicon carbide field effect transistor; and a driver integrated circuit which may include a differential amplifier coupled with a drain of the sensing field effect transistor and with a ground. The differential amplifier may be configured to output a gate reference voltage in response to receiving a drain current from the sensing field effect transistor. A first detection bipolar junction transistor may be included where a gate of the first bipolar junction transistor may be coupled to the gate reference voltage and a collector of the first bipolar junction transistor coupled to a reference current source forming a current mirror. A first comparator may be coupled to the collector of the first bipolar junction transistor, the first comparator configured to output a detected voltage signal when the gate reference voltage reaches a predetermined voltage level allowing current flow to an emitter of the first bipolar transistor. The driver integrated circuit may be configured to receive the detected voltage signal identifying a first fault condition and, in response, shut down operation of the silicon carbide field effect transistor.

Implementations of circuit protection system may include one, all, or any of the following:

The first fault condition may be one of an overcurrent condition or a short circuit condition.

The system may include a second detection bipolar junction transistor, a gate of the second bipolar junction transistor coupled to the gate reference voltage and a collector of the second bipolar junction transistor coupled to the reference current source forming the current mirror; and a second comparator coupled to the collector of the second bipolar junction transistor, the second comparator configured to output a second detected voltage signal when the gate reference voltage reaches a predetermined voltage level allowing current flow to an emitter of the second bipolar transistor. The driver integrated circuit may be configured to receive the second detected voltage signal identifying a second fault condition and, in response, shut down operation of the silicon carbide field effect transistor.

The second fault condition may be one of an overcurrent condition or a short circuit condition.

The system may include: a third detection bipolar junction transistor, a gate of the third bipolar junction transistor coupled to the gate reference voltage and a collector of the third bipolar junction transistor coupled to a monitoring current voltage source, the third bipolar junction transistor configured to: when the gate reference voltage reaches a predetermined voltage level, allow monitoring current flow from a collector to an emitter of the third bipolar transistor. The driver integrated circuit may be configured to receive the monitoring current flow and, if the monitoring current flow reaches or exceeds a predetermined threshold value, identify a third fault condition and, in response, shut down operation of the silicon carbide field effect transistor.

The third fault condition may be one of an overcurrent condition or a short circuit condition.

No external components to the driver integrated circuit and the silicon carbide field effect transistor may be included.

The external components may include one of a resistor, a capacitor, or a diode.

Implementations of a circuit protection system may include a sensing field effect transistor, a gate of the sensing field effect transistor configured to be coupled with a gate of a silicon carbide field effect transistor; and a driver integrated circuit may include a first transistor coupled with a reference current source configured to generate a reference voltage. A second transistor may be coupled with a constant current source, a gate of the second transistor coupled to the reference voltage; and a first comparator coupled to the source of the second transistor, the first comparator configured to generate a first output voltage signal corresponding with an over current condition when a sensing current from a drain of the sensing field effect transistor may be equal to or greater than the constant current source. The driver integrated circuit may be configured to receive the first output voltage signal identifying an overcurrent condition and, in response, shut down operation of the silicon carbide field effect transistor.

Implementations of a circuit protection system may include one, all, or any of the following:

The system may include a fourth transistor coupled with the sensing current from the drain of the sensing field effect transistor and with the reference current source; a third transistor coupled with the fourth transistor; and a second comparator coupled with a source of the fourth transistor. The third transistor and fourth transistor may be configured to, when the sensing current from the drain of the sensing field effect transistor may be equal to or greater than the constant current source, allow current flow through the third transistor where when current flows through the third transistor, current flows through the fourth transistor through a current mirror if the current flowing through the fourth transistor may be greater than the constant current source, and the second comparator may be configured to generate a second output voltage signal indicating a short circuit condition. The driver integrated circuit may be configured to receive the second output voltage signal identifying the short circuit condition and, in response, shut down operation of the silicon carbide field effect transistor.

The system may be able to detect both the overcurrent condition and the short circuit condition simultaneously.

The threshold voltage for the overcurrent condition may be two times lower than a threshold voltage for the short circuit condition.

The voltage ratio of the first transistor to the second transistor may be 1:1000.

The voltage ratio of the third transistor to the second transistor may be 1:1000.

No external components to the driver integrated circuit and the silicon carbide field effect transistor may be included.

The external components may include one of a resistor, a capacitor, or a diode.

The first transistor, second transistor, third transistor, and fourth transistor may be field effect transistors.

Implementations of a method of protecting a field effect transistor may include providing a sensing field effect transistor, a gate of the sensing field effect transistor coupled with a gate of a field effect transistor and a driver integrated circuit, where the driver integrated circuit may include a first transistor coupled with a reference current source; a second transistor coupled with a constant current source; and a first comparator coupled to the source of the second transistor. The method may include generating a reference voltage with the first transistor and the reference current source where a gate of the second transistor is coupled to the reference voltage. The method may include when a sensing current from the drain of the sensing field effect transistor may be equal to or greater than the constant current source, generating a first output voltage signal corresponding with an overcurrent condition using the first comparator; receiving the first output voltage signal identifying the overcurrent condition at the driver integrated circuit; and further providing: a fourth transistor coupled with the sensing current from the drain of the sensing field effect transistor and with the reference current source; a third transistor coupled with the fourth transistor; and a second comparator coupled with the source of the fourth transistor. The method may include when the sensing current from a drain of the sensing field effect transistor is equal to or greater than the constant current source, allowing current flow through the third transistor and corresponding current flow through the fourth transistor through a current mirror. The method may include if the current flowing through the fourth transistor is greater than the constant current source, generating a second output voltage signal indicating a short circuit condition using the second comparator; and receiving the second output voltage signal identifying the short circuit condition at the driver integrated circuit.

Implementations of a method of protecting a field effect transistor may include one, all or any of the following:

The method may include, in response to simultaneously receiving the first output voltage signal and the second output voltage signal, shutting down operation of the field effect transistor.

The method may include, in response to receiving either the first output voltage signal or the second output voltage signal, shutting down operation of the field effect transistor.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a schematic of an implementation of a short circuit protection circuit;

FIG. 2 is a schematic of another implementation of a short circuit protection circuit;

FIG. 3 is a schematic of an implementation of a circuit protection system coupled with a field effect transistor (FET);

FIG. 4 is a schematic of an implementation of a circuit protection system coupled with a half bridge inverter;

FIG. 5 is a schematic of an implementation of a circuit protection system coupled with a half bridge inverter; and

FIG. 6 is a graph of the results of a simulation used to compare the signaling performance of an implementation of a circuit protection system like that illustrated in FIGS. 3-4 with that of a one like that illustrated in FIG. 1.

### DESCRIPTION

This disclosure, its aspects and implementations, are not limited to the specific components, assembly procedures or method elements disclosed herein. Many additional components, assembly procedures and/or method elements known in the art consistent with the intended circuit protection systems will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such circuit protection systems, and implementing components and methods, consistent with the intended operation and methods.

Silicon carbide (SiC) MOSFETs are being used to replace silicon insulated gate bipolar transistors (IGBTs) and silicon MOSFETs because they exhibit various desirable electrical characteristics including, by non-limiting example, high voltage capability, high power density (low Rds_on), high switching speed, high temperature capability, high efficiency in power converting applications, and other desired electrical/performance characteristics. Since the current density of silicon carbide devices is high relative to silicon devices, such devices accumulate thermal stresses faster which can lead to faster structural damage in a short circuit or overcurrent situation then in comparable silicon devices. Thus, silicon carbide devices have a shorter short circuit withstand time (SCWT) than comparable silicon devices. Accordingly, to prevent damage to the silicon carbide devices, the ability to detect a short circuit or overcurrent condition in a short time window and turn off a SiC MOSFET is an important part of the design of the overall system that incorporates the SiC MOSFET including a driver integrated circuit (Driver IC) included in the system. Various systems that work to provide short circuit protection, overcurrent protection (OCP) and current monitoring (IMON) have been devised that utilize multiple field effect transistors (FETs) that operate in conjunction with detection/control circuit components to monitor SiC FETs during operation (SENSE FETs). While the examples in this document apply these principles to SiC FETs, the circuits and principles could be applied to other FETs formed on different substrates, including, by non-limiting example, silicon, silicon on insulator, sapphire, ruby, gallium arsenide, gallium nitride, or other semiconductor substrate material types.

The challenge with the use of SENSE FETs is often the increase in size and complexity of the SiC FET die and/or any driver/controller semiconductor die used in the system caused by the inclusion of the various circuit components used in conjunction with the SENSE FETs. Referring to FIG. 1, an example of a circuit 1 used to perform sensing of a SiC FET is illustrated. Here in this system, the components in box 2 are included on a driver integrated circuit (driver IC or driver semiconductor die) and the components in the red circle 4 (external components) are two external diodes, a resistor, and a capacitor that are included in the circuit separate from the driver IC and from the SiC FET 5 being monitored. The external components 4 need to have a high voltage rating as they are coupled to the drain side of the SiC FET 5 and so experience the full voltage being handled by the SiC FET 5. This particular circuit 1 operates using a desaturation method where detection of an overcurrent or short circuit condition is identified by sensing the drain voltage with the components in box 2 in combination with the external diode and capacitor of the external components 4. It has been observed that this technique and system is subject to inaccuracies and results in false detections leading to unnecessary deactivation of the SiC FET in electrically noisy environments. The additional challenge this desaturation system has is that the ability this circuit 1 has to respond quickly to an overcurrent situation is compromised by its observation of only the exiting drain voltage which means that the circuit 1 is unable to sense/observe the actual current passing through the SiC FET 6 itself as rapidly. This circuit 1 of FIG. 1 is a local sensing approach that directly measures the drain voltage output of the SiC FET 6.

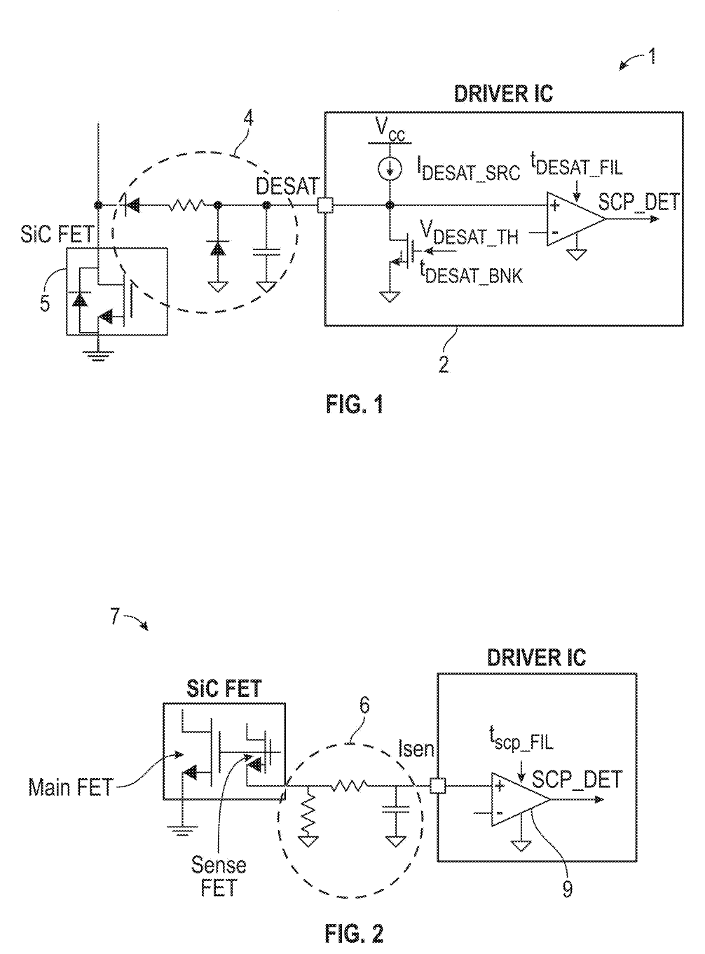

Other systems have involved using a remote sensing (rSENSE) approach like as in the circuit 7 illustrated in FIG. 2. In this implementation, a sensing (SENSE) FET is coupled to the gate of the SiC FET (Main FET) and the parallel orientation of the sensing FET means that when the gate voltage of the SiC FET reaches a certain predetermined level, current begins to flow through the sensing FET. External components 6 in this implementation include two resistors and a capacitor which then output a signal received on a pin (Isen) of the driver IC 9 which is then compared with reference voltage using a comparator 9. If the comparator returns an output that indicates that an overcurrent condition exists, that signal then is used to trigger the shutdown of the SiC FET. Challenges with this design are that back-bias of the sensing FET itself can make the analysis inaccurate and again, additional external passive components (resistor, capacitor, etc.) are needed to get it to operate. This design also has lower electrical noise immunity and so can cause false shutdowns of the SiC FET in an electrically noisy environment.

The various overcurrent, short circuit, and IMON detecting systems and related methods disclosed herein are designed to not include external components that need to be added to a circuit outside a SiC FET itself or a driver integrated circuit. These various systems are also designed to achieve faster detection of the overcurrent and short circuit conditions (fault conditions) to help minimize risks of damage to SiC FET systems.

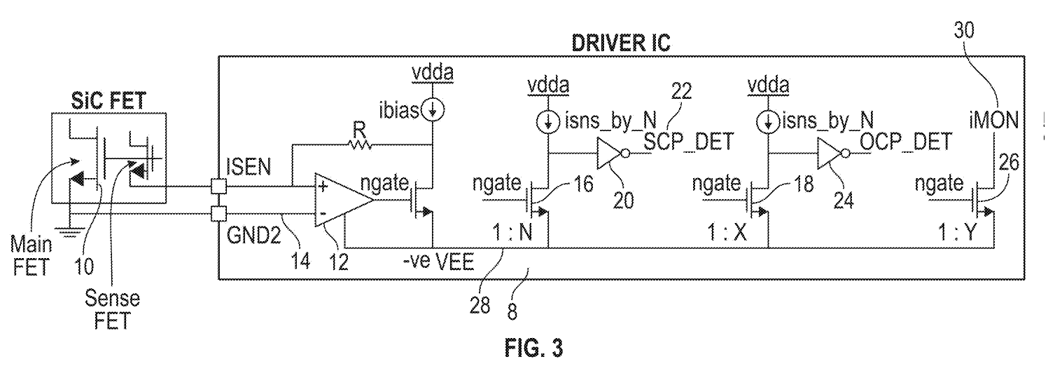

Referring to FIG. 3, an implementation of a circuit protection system 8 integrated into a driver IC is illustrated coupled to SiC FET 10. As with the implementation in FIG. 2, a gate of a SENSE FET is coupled with the gate of the SiC FET 10 and is configured to allow current to pass from its source to drain when the gate voltage of the SiC FET reaches a certain threshold, causing sense current ISEN to flow through the SENSE FET which is received on one pin ISEN of the driver IC. As illustrated in FIG. 3, the sense current is then received by a differential amplifier 12 that has a reference voltage 14 connected to a common ground with the SiC FET at a ground pin GND2 of the driver IC. The output of the differential amplifier is a reference voltage “ngate” which is then connected with the gate of a first bipolar junction transistor (BJT) 16 or other transistor type (MOSFET, etc.) to supply its gate voltage. The internal ngate voltage is used to set up a current mirror with the first BJT 16 and a second BJT 18 coupled in a common emitter configuration where the ngate voltage is also connected to the gate of the second BJT 18. In some implementations, depending on the electrical characteristics of the first and second BJTs 16, 18 used in the current mirror, a ratioing of the output current from the current mirror can be achieved while using the same internal ngate voltage applied to the gates of both transistors (1:N, 1:X) as illustrated in the implementation of FIG. 3). A reference current isns_by_N is applied to the collector side of the first BJT 16 and second BJT 18 in the current mirror and current flows through the BJTs 16, 18. When the ngate voltage reaches a predetermined threshold when a short circuit condition in the SiC FET is reached, the short circuit condition is detected using a comparator 20 that outputs a short circuit protection voltage signal (SCP_DET) 22. As illustrated, a comparator 24 is also coupled to the second BJT 18 and the second BJT 18 is designed/sized so that when the ngate voltage reaches a predetermined threshold, the comparator outputs an overcurrent protection voltage signal (OCP_DET) when an overcurrent or short circuit condition at the SiC FET is present. The OCP_DET signal may be sent at the same time or at a different time as the SCP_DET signal depending on the structure of the current mirror and the operating condition of the SIC FET at that time. When the circuit protection system 8 senses an overcurrent or short circuit condition in the SiC FET, the SCP_DET and/or OCP_DET voltage signals are used by the driver IC to shut down/turn off the SiC FET.

In the implementation illustrated in FIG. 3, as part of the current mirror, an additional circuit used to monitor the current flowing through the SIC FET is also illustrated. This circuit includes a third BJT 26 with the desired electrical characteristics to generate the shared emitter voltage VEE 28 as monitoring current iMON passes through the third BJT 26. During operation, the ngate voltage is applied to the gate of the third BJT 26 while a monitoring current voltage source 30 is applied to the collector side of the third BJT 26. The magnitude of the monitoring current iMON 30 that passes through the third BJT 26 during application of the ngate voltage to the gate of the third BJT 26 is used to calculate the current passing through the SiC FET. When the monitoring current iMON 30 reaches a predetermined level, in some implementation, the system may trigger the driver IC to initiate a shutdown of the SiC FET whether or not the short circuit signal or overcurrent protection signals have been detected (if they are present in the system). In other implementations, after the monitoring current iMON 30 surpasses the predetermined level, the system 8 may wait until an overcurrent and/or short circuit signal is also present before the driver IC initiates a shutdown of the SiC FET.

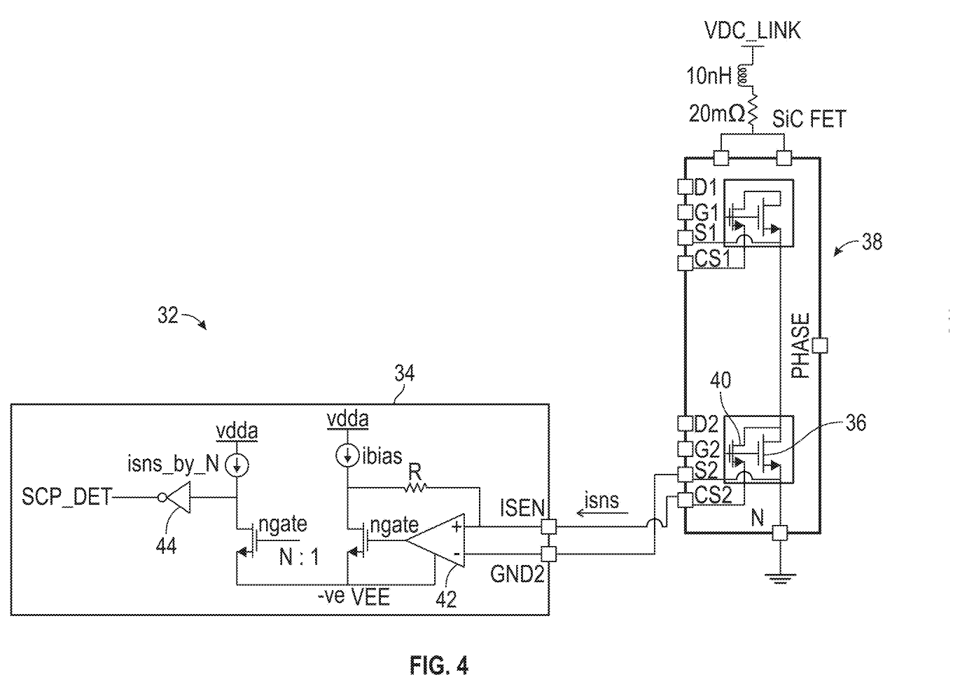

Referring to FIG. 4, a non-limiting example of implementation of a circuit protection system 32 is illustrated that has the circuit protection system included in driver IC 34 connected to one SiC FET 36 that is one of two SiC FETs included in a half bridge inverter circuit 38. Like the example in FIG. 3, the circuit protection system 32 also involves a remote sensing configuration. The gate of sense FET 40 is illustrated coupled to the gate of the SiC FET 36 and a resulting sense current ISEN (isns) is illustrated being received from pin CS2 onto one pin of a driver IC 34 (ISEN) that includes the circuit protection system. Like the circuit in FIG. 3, a ground pin (GND2) couples the system 32 to the ground of the SiC FET 36. While not shown in FIG. 4, another circuit protection system may be coupled to the other SiC FET in the half bridge and included in the driver IC 34 (or a different driver IC coupled to the other SiC FET) to simultaneously monitor the performance of the SiC FET in the same or substantially the same way. In the circuit protection system 32 of FIG. 4, only one differential amplifier (comparator) 42 is illustrated that outputs an ngate voltage signal to a current mirror similar to the system illustrated in FIG. 3. The current mirror in this implementation generates a short circuit (short circuit protection SCP_DET) signal using comparator 44 and reference current isns_by_N that the driver IC can then use to shut down/turn off the SiC FET 36 if the comparator signals a short circuit condition exists. Here the circuit protection system 32 only includes the components to monitor for a short circuit condition, but in other implementations, the additional components to monitor for overcurrent and/or current flow (iMON) may be included similar to the system illustrated in FIG. 3.

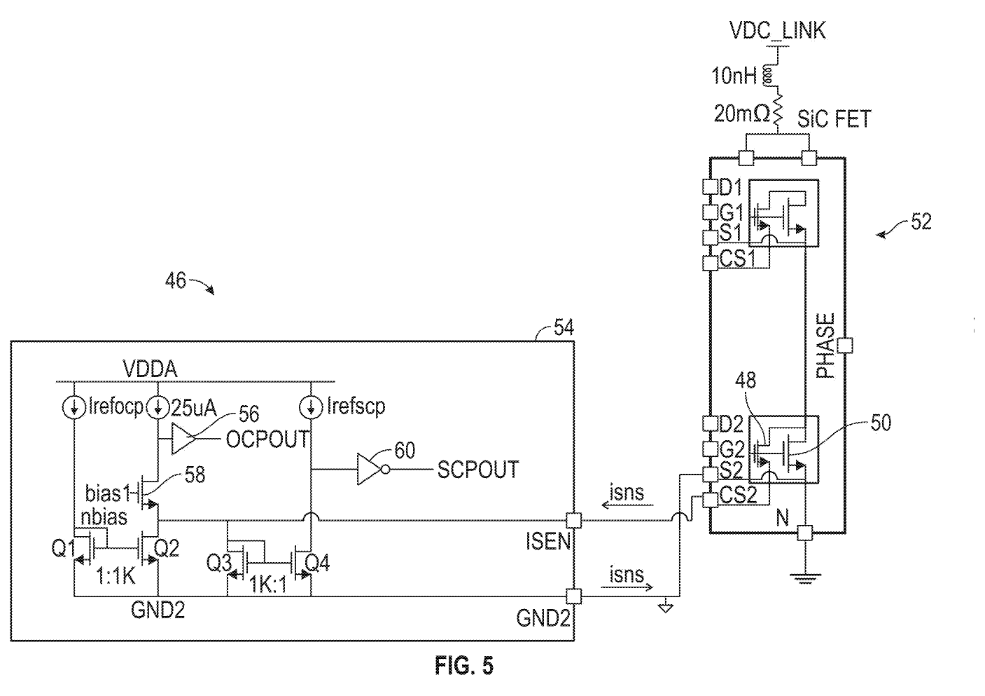

Other circuit protection system designs may be constructed that employ only on-driver IC circuit designs and exclude external components. Referring to FIG. 5, another circuit protection system implementation 46 is illustrated. Like the systems of FIGS. 3-4, the system employs a sense FET 48 coupled with the gate of one of the SiC FETs 50 arranged in a half bridge device 52 like that illustrated in FIG. 4 to generate sense current isns which is then received on current sensing pin ISEN of the driver IC 54. A ground pin GND2 is also connected with the ground of the SiC FET 50. In this implementation, a reference voltage nbias is generated using transistor Q1 using reference current Irefocp (reference current source). This reference voltage nbias is used for detecting both an overcurrent condition and a short circuit condition. Because in this implementation the threshold voltage for overcurrent is about 2 times lower than that of short circuit, the electrical parameters of transistors Q2, Q3, and Q4 are set (voltage ratio, etc.) to achieve the desired ratio of sensitivity/detection for identifying overcurrent and short current conditions. In a particular implementation, the voltage ratio of the voltage of the transistor Q1 to the voltage of transistor Q2 is 1:1000. In a particular implementation, the voltage ratio of the voltage of the transistor Q3 to the voltage of the transistor Q4 is 1:1000.

In this implementation, the nbias voltage is applied to the gate of transistor Q2 which then opens and allows sense current isns to flow to ground when the sense current isns reaches a certain predetermined level and thus providing an input to the comparator 56. The comparator 56 is coupled to a constant current source set at 25 micro Amperes (as a non-limiting example). If isns is less than the reference Irefocp, then the comparator provides no voltage signal as no current flows through bias transistor 58. If isns is equal to or higher than the reference Irefocp, then the comparator 56 provides an output voltage signal as current now begins to flow through bias transistor 58. The output voltage signal of the comparator 56 is an overcurrent detection voltage (OCPOUT) which the driver IC 54 then receives and uses to deactivate/turn off the SiC FET 50 in response to detection of an overcurrent situation.

If isns also is greater than Irefscp being supplied to transistor Q4, then the circuit permits the sense current to flow through transistor Q3 and to ground. The isns current is mirrored in transistor Q4 the current flowing through transistor Q4 is compared against the reference current Irefscp used to detect a short circuit condition. If the isns current through transistor Q4 is less than Irefscp, then comparator 60 produces no output voltage. If the isns current through transistor Q4 is greater than Irefscp, then the comparator 60 produces output voltage SCPOUT which is then used by the driver IC 54 to deactivate/turn off the SiC FET 50 in response to detection of a short circuit condition. This ability to use the same input sense current isns in simultaneously detecting both overcurrent and short circuit conditions using the circuit protection system 46 implementation of FIG. 5 may work to speed up the detection of both of these conditions and prevent/limit damage to the SiC FET 50 being monitored. In various implementations, the system 32 of FIG. 5 may also be modified to allow for tracking of monitoring current iMON by the driver IC 54 using the principles previously disclosed in the implementation illustrated in FIG. 3.

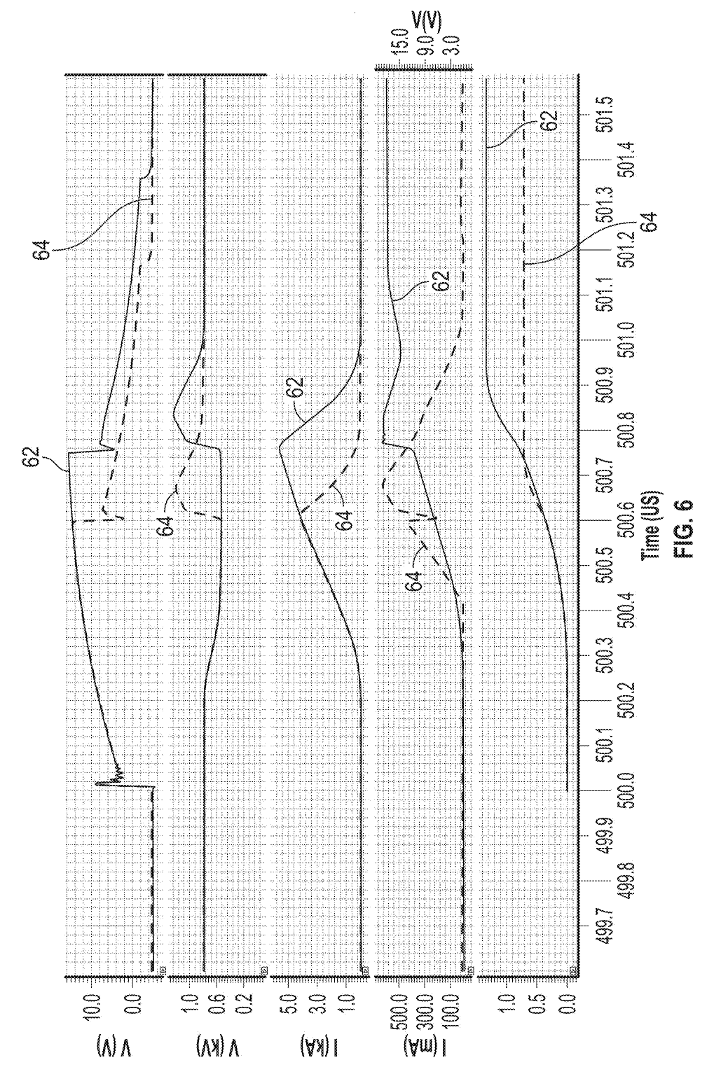

Referring to FIG. 6, an implementation of a circuit protection system like those illustrated in FIGS. 3-4 was utilized in a simulation to compare the signaling performance with a circuit protection system like that illustrated in FIG. 1. A threshold amperage of 1230 Amps was used as a threshold for both systems in the simulation. In this implementation, the waveforms 62 compared to the waveforms 64 show that the implementation of FIGS. 3-4 consistently signaled faster than the implementation of FIG. 1. The faster signaling means that the corresponding driver IC will have the ability to take action faster to shut down the SiC FET to prevent damage to the SiC FET being monitored. As previously discussed, this can prevent damage to SiC FETs which are more time sensitive to overcurrent and short circuit conditions than silicon FETs.

Implementations of circuit protection systems like those illustrated in FIG. 5 may utilize a method of protecting a field effect transistor. The method may include providing a sensing field effect transistor where a gate of the sensing field effect transistor is coupled with a gate of a field effect transistor and a driver integrated circuit. The driver integrated circuit includes a first transistor coupled with the reference current source, a second transistor coupled with a constant current source, and a first comparator coupled to the source of the second transistor. The method includes generating a reference voltage with the first transistor and the reference current source where a gate of the second transistor is coupled to the reference voltage. The method includes when a sensing current from the drain of the sensing field effect transistor is equal to or greater than the constant current source, generating a first output voltage signal corresponding with an overcurrent condition curing the first comparator. The method also includes receiving the first output voltage signal identifying the overcurrent condition at the driver integrated circuit. The method also includes providing a fourth transistor coupled with the sensing current from the drain of the sensing field effect transistor and with the reference current source, a third transistor coupled with the fourth transistor, a second comparator coupled with the source of the fourth transistor, and a second comparator coupled with the source of the fourth transistor. The method includes when the sensing current from the drain of the sensing field effect transistor is equal to or greater than the constant current source, allowing current flow through the third transistor and corresponding current flow through the fourth transistor through a current mirror. If the current flowing through the fourth transistor is greater than the constant current source, generating a second output voltage signal indicating a short circuit condition using the second comparator. The method also includes receiving the second output voltage signal identifying the short circuit condition at the driver integrated circuit.

The foregoing method utilizes the various components previously described with respect to FIG. 5 but can be implemented using any FET type disclosed herein including an SiC FET. In a particular implementation, the method includes, in response to simultaneously receiving the first output voltage signal and the second output voltage signal, shutting down operation of the field effect transistor. In other implementations, the method includes, in response to receiving either the first output voltage signal or the second output voltage signal, shutting down operations of the field effect transistor. Other method implementations and variations are possible using the principles and components disclosed herein.

In places where the description above refers to particular implementations of circuit protection systems and implementing components, sub-components, methods and sub-methods, it should be readily apparent that a number of modifications may be made without departing from the spirit thereof and that these implementations, implementing components, sub-components, methods and sub-methods may be applied to other circuit protection systems.

What is claimed is:

1. A circuit protection system comprising:
a sensing field effect transistor, a gate of the sensing field effect transistor configured to be coupled with a gate of a silicon carbide field effect transistor; and
a driver integrated circuit comprising:
a differential amplifier coupled with a drain of the sensing field effect transistor and with a ground, the differential amplifier configured to output a gate reference voltage in response to receiving a drain current from the sensing field effect transistor;
a first detection bipolar junction transistor, a gate of the first bipolar junction transistor coupled to the gate reference voltage and a collector of the first bipolar junction transistor coupled to a reference current source forming a current mirror; and
a first comparator coupled to the collector of the first bipolar junction transistor, the first comparator configured to output a detected voltage signal when the gate reference voltage reaches a predetermined voltage level allowing current flow to an emitter of the first bipolar transistor;
wherein the driver integrated circuit is configured to receive the detected voltage signal identifying a first fault condition and, in response, shut down operation of the silicon carbide field effect transistor.

2. The system of claim 1, wherein the first fault condition is one of an overcurrent condition or a short circuit condition.

3. The system of claim 1, further comprising:
a second detection bipolar junction transistor, a gate of the second bipolar junction transistor coupled to the gate reference voltage and a collector of the second bipolar junction transistor coupled to the reference current source forming the current mirror; and
a second comparator coupled to the collector of the second bipolar junction transistor, the second comparator configured to output a second detected voltage signal when the gate reference voltage reaches a predetermined voltage level allowing current flow to an emitter of the second bipolar transistor;
wherein the driver integrated circuit is configured to receive the second detected voltage signal identifying a second fault condition and, in response, shut down operation of the silicon carbide field effect transistor.

4. The system of claim 3, wherein the second fault condition is one of an overcurrent condition or a short circuit condition.

5. The system of claim 3, further comprising:
a third detection bipolar junction transistor, a gate of the third bipolar junction transistor coupled to the gate reference voltage and a collector of the third bipolar junction transistor coupled to a monitoring current voltage source, the third bipolar junction transistor configured to:
when the gate reference voltage reaches a predetermined voltage level, allow monitoring current flow from a collector to an emitter of the third bipolar transistor;
wherein the driver integrated circuit is configured to receive the monitoring current flow and, if the monitoring current flow reaches or exceeds a predetermined threshold value, identify a third fault condition and, in response, shut down operation of the silicon carbide field effect transistor.

6. The system of claim 5, wherein the third fault condition is one of an overcurrent condition or a short circuit condition.

7. The system of claim 1, wherein no external components to the driver integrated circuit and the silicon carbide field effect transistor are included.

8. The system of claim 7, wherein the external components include one of a resistor, a capacitor, or a diode.

9. A circuit protection system comprising:
a sensing field effect transistor, a gate of the sensing field effect transistor configured to be coupled with a gate of a silicon carbide field effect transistor; and
a driver integrated circuit comprising:
a first transistor coupled with a reference current source configured to generate a reference voltage;
a second transistor coupled with a constant current source, a gate of the second transistor coupled to the reference voltage; and
a first comparator coupled to the source of the second transistor, the first comparator configured to generate a first output voltage signal corresponding with an over current condition when a sensing current from a drain of the sensing field effect transistor is equal to or greater than the constant current source;
wherein the driver integrated circuit is configured to receive the first output voltage signal identifying an overcurrent condition and, in response, shut down operation of the silicon carbide field effect transistor.

10. The system of claim 9, further comprising:
a fourth transistor coupled with the sensing current from the drain of the sensing field effect transistor and with the reference current source;
a third transistor coupled with the fourth transistor; and
a second comparator coupled with a source of the fourth transistor;
wherein the third transistor and fourth transistor are configured to, when the sensing current from the drain of the sensing field effect transistor is equal to or greater than the constant current source, allow current flow through the third transistor;
wherein when current flows through the third transistor, current flows through the fourth transistor through a current mirror
if the current flowing through the fourth transistor is greater than the constant current source, and the second comparator is configured to generate a second output voltage signal indicating a short circuit condition; and
wherein the driver integrated circuit is configured to receive the second output voltage signal identifying the short circuit condition and, in response, shut down operation of the silicon carbide field effect transistor.

11. The system of claim 10, wherein the system can detect both the overcurrent condition and the short circuit condition simultaneously.

12. The system of claim 10, wherein a threshold voltage for the overcurrent condition is two times lower than a threshold voltage for the short circuit condition.

13. The system of claim 10, wherein a voltage ratio of the first transistor to the second transistor is 1:1000.

14. The system of claim 10, wherein a voltage ratio of the third transistor to the second transistor is 1:1000.

15. The system of claim 9, wherein no external components to the driver integrated circuit and the silicon carbide field effect transistor are included.

16. The system of claim 15, wherein the external components include one of a resistor, a capacitor, or a diode.

17. The system of claim 9, wherein the first transistor, second transistor, third transistor, and fourth transistor are field effect transistors.

18. A method of protecting a field effect transistor, the method comprising:
providing a sensing field effect transistor, a gate of the sensing field effect transistor coupled with a gate of a field effect transistor and a driver integrated circuit, the driver integrated circuit comprising:
a first transistor coupled with a reference current source;
a second transistor coupled with a constant current source; and
a first comparator coupled to the source of the second transistor,
generating a reference voltage with the first transistor and the reference current source where a gate of the second transistor coupled to the reference voltage;
when a sensing current from the drain of the sensing field effect transistor is equal to or greater than the constant current source, generating a first output voltage signal corresponding with an overcurrent condition using the first comparator;
receiving the first output voltage signal identifying the overcurrent condition at the driver integrated circuit;
further providing:
a fourth transistor coupled with the sensing current from the drain of the sensing field effect transistor and with the reference current source;
a third transistor coupled with the fourth transistor; and
a second comparator coupled with the source of the fourth transistor;
when the sensing current from a drain of the sensing field effect transistor is equal to or greater than the constant current source, allowing current flow through the third transistor and corresponding current flow through the fourth transistor through a current mirror;
if the current flowing through the fourth transistor is greater than the constant current source, generating a second output voltage signal indicating a short circuit condition using the second comparator; and
receiving the second output voltage signal identifying the short circuit condition at the driver integrated circuit.

19. The method of claim 18, further comprising, in response to simultaneously receiving the first output voltage signal and the second output voltage signal, shutting down operation of the field effect transistor.

20. The method of claim 18, further comprising, in response to receiving either the first output voltage signal or the second output voltage signal, shutting down operation of the field effect transistor.
